(19) United States
(12) Patent Application Publication
(10) Pub. No.: US 2014/0035525 A1
(43) Pub. Date: Feb. 6, 2014

(54) SYSTEM TO CONTROL WHEN ELECTRICITY IS PROVIDED TO AN INDUCTIVE LOAD AND METHOD OF PROVIDING AND USING THE SAME

(71) Applicants: Camron Vossberg, Tempe, AZ (US); Dimitri Hochard, Scottsdale, AZ (US); Travers Buda, Tempe, AZ (US)

(72) Inventors: Camron Vossberg, Tempe, AZ (US); Dimitri Hochard, Scottsdale, AZ (US); Travers Buda, Tempe, AZ (US)

(73) Assignee: Electric Transportation Engineering Corp., dba ECOtality North America, Phoenix, AZ (US)

(21) Appl. No.: 13/563,539

(22) Filed: Jul. 31, 2012

(51) Int. Cl. H01H 47/32; H02P 13/00; H05K 13/00; H02J 7/02

(52) U.S. Cl. 320/109; 307/104; 361/185; 29/825

(57) ABSTRACT

Some embodiments include a system to control when electricity is provided to an inductive load. Other embodiments of related systems and methods are also disclosed.

### FIELD OF THE INVENTION

This invention relates generally to a system and method to control when electricity is provided to an inductive load, and relates more particularly to such a system and method that mitigates electric emissions conducted and radiated by the inductive load by controlling when the inductive load starts and stops receiving electricity so that the starts coincide with a voltage zero crossing condition of the electricity and the stops coincide with a current zero crossing condition of the electricity.

### DESCRIPTION OF THE BACKGROUND

Conducted and/or radiated electric emissions (e.g., electrical noise) that are emitted by an inductive load (e.g., a relay or contactor) controlled by alternating current electricity can interfere with and/or damage electrical systems positioned around the inductive load that receive the electric emissions. Accordingly, a need or potential for benefit exists for a system that mitigates or eliminates the electric emissions of an inductive load controlled by alternating current electricity.

### BRIEF DESCRIPTION OF THE DRAWINGS

To facilitate further description of the embodiments, the following drawings are provided in which:

FIG. 1 illustrates a block diagram of a system, according to an embodiment;

FIG. 2 illustrates an electric circuit, according to an embodiment;

FIG. 3 is a graph showing line (e.g., mains line) voltages from an electricity source coupled to the electric circuit of FIG. 2 and a voltage at an inductive load of the electric circuit of FIG. 2, both as a function of time, according to the embodiment of FIG. 2;

FIG. 4 is a graph showing an electric current passing through a switch of the electric circuit of FIG. 2, as a function of time, according to the embodiment of FIG. 2;

FIG. 5 is a graph showing an electric current flowing through the inductive load of the electric circuit of FIG. 2, as a function of time, when the inductive load initially stops receiving electricity from the electricity source coupled to the electric circuit and the electricity is in the current zero crossing condition;

FIG. 6 is a graph showing an electric voltage at the inductive load of the electric circuit of FIG. 2, as a function of time, when inductive load initially stops receiving electricity from the electricity source coupled to the electric circuit and the electricity is in the current zero crossing condition;

FIG. 7 is a graph showing an electric voltage at a capacitor of the inductive load of the electric circuit of FIG. 2, as a function of time, when the inductive load initially stops receiving electricity from the electricity source and the electricity is in the current zero crossing condition;

FIG. 8 is a graph showing an electric current flowing through the inductive load of the electric circuit of FIG. 2, as a function of time, when the inductive load initially stops receiving electricity from the electricity source coupled to the electric circuit and the electricity is in the voltage zero crossing condition;

FIG. 9 is a graph showing an electric voltage at the inductive load of the electric circuit of FIG. 2, as a function of time, when inductive load initially stops receiving electricity from the electricity source coupled to the electric circuit and the electricity is in the voltage zero crossing condition;

FIG. 10 is a graph showing an electric voltage at a capacitor of the inductive load of the electric circuit of FIG. 2, as a function of time, when the inductive load initially stops receiving electricity from the electricity source and the electricity is in the voltage zero crossing condition;

FIG. 11 is a graph showing an electric current flowing through the inductive load of the electric circuit of FIG. 2, as a function of time, when the inductive load initially stops receiving electricity from the electricity source coupled to the electric circuit and the electricity is in the current zero crossing condition, including the effect of a voltage transient suppression module;

FIG. 12 is a graph showing an electric voltage at the inductive load of the electric circuit of FIG. 2, as a function of time, when inductive load initially stops receiving electricity from the electricity source coupled to the electric circuit and the electricity is in the current zero crossing condition, including the effect of the voltage transient suppression module;

FIG. 13 is a graph showing an electric voltage at a capacitor of the inductive load of the electric circuit of FIG. 2, as a function of time, when the inductive load initially stops receiving electricity from the electricity source and the electricity is in the current zero crossing condition, including the effect of the voltage transient suppression module;

FIG. 14 illustrates a block diagram of a system, according to an embodiment;

FIG. 15 illustrates a flow chart for an embodiment of a method of manufacturing a system;

FIG. 16 illustrates an exemplary activity of providing a control module configured to control when an inductive load module of an electric circuit receives electricity from an electricity source, according to the embodiment of FIG. 15;

FIG. 17 illustrates an exemplary activity of providing the electric circuit, according to the embodiment of FIG. 15;

FIG. 18 illustrates an exemplary activity of providing a voltage transient suppression module, according to the embodiment of FIG. 15;

FIG. 19 illustrates a flow chart for an embodiment of a method;

FIG. 20 illustrates an exemplary activity of controlling when an inductive load module of an electric circuit receives electricity from an electricity source, according to the embodiment of FIG. 20;

FIG. 21 illustrates a computer system that is suitable for implementing an embodiment of a control module and/or a computer system of a charging system; and

FIG. 22 illustrates a representative block diagram of an example of the elements included in the circuit boards inside a chassis of the computer system of FIG. 21.

For simplicity and clarity of illustration, the drawing figures illustrate the general manner of construction, and descriptions and details of well-known features and techniques may be omitted to avoid unnecessarily obscuring the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Furthermore, the terms “include,” and “have,” and any variations thereof, are intended to cover a non-exclusive inclusion, such that a process, method, system, article, device, or apparatus that comprises a list of elements is not necessarily limited to those elements, but may include other elements not expressly listed or inherent to such process, method, system, article, device, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein.

The terms “couple,” “coupled,” “couples,” “coupling,” and the like should be broadly understood and refer to connecting two or more elements or signals, electrically, mechanically and/or otherwise. Two or more electrical elements may be electrically coupled together, but not be mechanically or otherwise coupled together; two or more mechanical elements may be mechanically coupled together, but not be electrically or otherwise coupled together; two or more electrical elements may be mechanically coupled together, but not be electrically or otherwise coupled together. Coupling may be for any length of time, e.g., permanent or semi-permanent or only for an instant.

“Electrical coupling” and the like should be broadly understood and include coupling involving any electrical signal, whether a power signal, a data signal, and/or other types or combinations of electrical signals. “Mechanical coupling” and the like should be broadly understood and include mechanical coupling of all types.

The absence of the word “removably,” “removable,” and the like near the word “coupled,” and the like does not mean that the coupling, etc. in question is or is not removable.

### DETAILED DESCRIPTION OF EXAMPLES OF EMBODIMENTS

Some embodiments include a system. The system comprises a control module configured to control when an inductive load module of an electric circuit receives electricity from an electricity source. The electric circuit comprises the inductive load module. Further, the electric circuit can be coupled to the electricity source. When the control module permits the inductive load module to receive the electricity from the electricity source, the inductive load module comprises an active state, and when the control module prevents the inductive load module from receiving the electricity from the electricity source, the inductive load module comprises an inactive state. Further, the electricity comprises a voltage zero crossing condition and a current zero crossing condition. In order to control when the inductive load module of the electric circuit receives the electricity from the electricity source: (a) the control module can cause the inductive load module (i) to switch from the inactive state to the active state and (ii) to switch from the active state to the inactive state; and (b) the control module is configured such that (i) when the control module causes the inductive load module to switch from the inactive state to the active state, the voltage zero crossing condition exists or is starting and (ii) when the control module causes the inductive load module to switch from the active state to the inactive state, the current zero crossing condition exists or is starting.

Various embodiments include a method of manufacturing a system. The method can comprising providing a control module configured to control when an inductive load module of an electric circuit receives electricity from an electricity source. The electric circuit comprises the inductive load module and can be coupled to the electricity source. When the control module permits the inductive load module to receive the electricity from the electricity source, the inductive load module comprises an active state, and when the control module prevents the inductive load module from receiving the electricity from the electricity source, the inductive load module comprises an inactive state. Further, the electricity comprises a voltage zero crossing condition and a current zero crossing condition. Meanwhile, providing the control module comprises: (a) configuring the control module to be able to cause the inductive load module (i) to switch from the inactive state to the active state and (ii) to switch from the active state to the inactive state; and (b) configuring the control module such that (i) when the control module causes the inductive load module to switch from the inactive state to the active state, the voltage zero crossing condition exists or is starting and (ii) when the control module causes the inductive load module to switch from the active state to the inactive state, the current zero crossing condition exists or is starting.

Further embodiments include a method. The method can comprise controlling when an inductive load module of an electric circuit receives electricity from an electricity source. The electric circuit comprises the inductive load module and can be coupled to the electricity source. Further, the electricity comprising a voltage zero crossing condition and a current zero crossing condition. Controlling when the inductive load module of the electric circuit receives the electricity from the electricity source can comprise: causing the inductive load module to begin receiving the electricity from the electricity source, the causing the inductive load module to begin receiving the electricity from the electricity source occurring when the voltage zero crossing condition exists or begins; and after causing the inductive load module to begin receiving the electricity from the electricity source, causing the inductive load module to stop receiving the electricity from the electricity source, the causing the inductive load module to stop receiving the electricity from the electricity source occurring when the current zero crossing condition exists or begins.

Other embodiments include an electric vehicle charging station. The electric vehicle charging station comprises an electric circuit and a control module. The electric circuit comprises a contactor and a voltage transient suppression module coupled in parallel with the contactor. Further, the electric circuit can be coupled to an electricity source and a rechargeable energy storage system of an electric vehicle. Meanwhile, the control module can control when the contactor receives electricity from the electricity source, and the electricity can comprise an alternating current. When the control module permits the contactor to receive the electricity from the electricity source, the contactor is closed, and when the control module prevents the contactor from receiving the electricity from the electricity source, the contactor is open. Further still, the electricity comprises a voltage zero crossing condition and a current zero crossing condition. In order to control when the contactor of the electric circuit receives the electricity from the electricity source: (a) the control module can cause the contactor (i) to close and (ii) to open; and (b) the control module is configured such that (i) when the control module causes the contactor to close, the voltage zero crossing condition exists or is beginning and (ii) when the control module causes the contactor to open, the current zero crossing condition exists or is beginning. Likewise, the electric circuit is configured such that when the contactor is closed and the rechargeable energy storage system is coupled to the electric circuit, the electric circuit can electrically charge the rechargeable energy storage system.

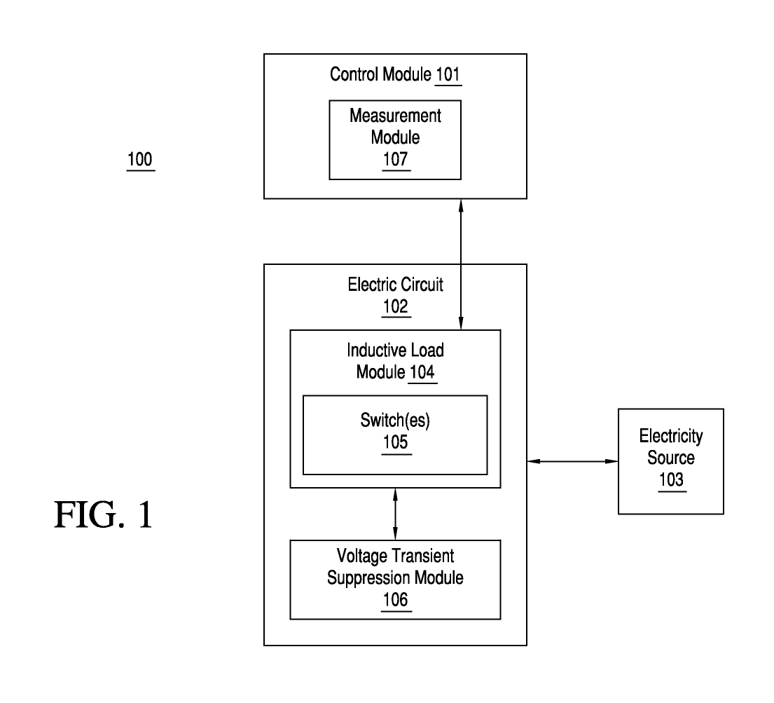

Turning to the drawings, FIG. 1 illustrates a block diagram of system 100, according to an embodiment. System 100 is merely exemplary and is not limited to the embodiments presented herein. System 100 can be employed in many different embodiments or examples not specifically depicted or described herein.

System 100 comprises control module 101. System 100 can comprise electric circuit 102 and electricity source 103. Further, electric circuit 102 comprises inductive load module 104. In many embodiments, inductive load module 104 comprises one or more switches 105. Switch(es) 105 can comprise any suitable device(s) configured to controllably complete and interrupt, or close and open, an electric circuit (e.g., electric circuit 102). For example, switch(es) 105 can comprise at least one relay and/or at least one contactor. Further, inductive load module 104 and/or switch(es) 105 can comprise one or more inductive loads. For example, as described below, the at least one contactor can comprise one or more of the inductive loads. Further, electric circuit 102 can comprise voltage transient suppression module 106 and/or control module 101. Voltage transient suppression module 106 can comprise a snubber circuit, which, for example, can comprise a resistor and a capacitor coupled together in series. In further embodiments, voltage transient suppression module 106 can comprise one or more metal oxide varistors. In other embodiments, voltage transient suppression module 106 can be devoid of any metal oxide varistors. In still other embodiments, voltage transient suppression module 106 can be omitted. In many embodiments, control module 101 can comprise measurement module 107.

Control module 101 can be coupled and/or in communication with electric circuit 102, inductive load 104, and/or switch(es) 105. Electric circuit 102, inductive load 104, and/or switch(es) 105 can be coupled with electricity source 103. Voltage transient suppression module 106 can be coupled to and/or across inductive load module 104. In many embodiments, voltage transient suppression module 106 can be coupled in parallel with part or all of inductive load module 104. For example, when switch(es) 105 comprise a relay and/or a contactor, voltage transient suppression module 106 can be coupled in parallel with the relay and/or the contactor. Meanwhile, when switch(es) 105 comprise a relay and a contactor, the relay and contactor can be coupled in series with each other.

Electricity source 103 can provide electricity to electric circuit 102 and/or inductive load module 104 when coupled (e.g., directly or indirectly) with electric circuit 102 and/or inductive load module 104. Accordingly, electricity source 103 can comprise any suitable source of electricity (e.g., an electric power mains) configured to provide that electricity to electric circuit 102 and/or inductive load module 104. In many embodiments, the electricity provided by electricity source 103 can comprise alternating current. Further, as alternating current electricity, the electricity can comprise a voltage zero crossing condition and a current zero crossing condition. The voltage zero crossing condition refers to a zero voltage condition of the electricity, and the current zero crossing condition refers to a zero current condition of the electricity. In theory, these conditions exist instantaneously when a sign (e.g., positive/negative) of the voltage or current, respectively, of a corresponding wave function of the electricity changes. However, practically speaking and as used herein, the voltage zero crossing condition can refer to when the voltage of the electricity is approximately zero, and the current zero crossing condition can refer to when the current of the electricity is approximately zero. For example, in some embodiments, the voltage zero crossing condition can refer to when the voltage of the electricity is within approximately ±3 volts of the zero voltage condition, and the current zero crossing condition can refer to when the current of the electricity is within approximately 5-6 milliamps of the zero current condition. In a more general example, the voltage crossing condition can refer to when the voltage of the electricity is within approximately ±1 percent, ±5 percent, and/or ±10 percent of zero volts with respect to a maximum voltage of the electricity, and the current zero crossing condition can refer to when the current of the electricity is within approximately 1 percent, 5 percent, and/or 10 percent of zero amps with respect to a maximum current of the electricity.

Meanwhile, control module 101 is configured to control when inductive load module 104 receives electricity from electricity source 103. In order to do so, control module 101 can cause inductive load module 104 to switch from an inactive state to an active state, and vice versa. In the active state, inductive load module 104 receives electricity from electricity source 103. Meanwhile, in the inactive state, inductive load module 104 does not receive electricity from electricity source 103. In many embodiments, control module 101 can control when inductive load module 104 receives electricity from electricity source 103 through control of one or more of switch(es) 105. Furthermore, one or more of switch(es) 105 can be operated by electricity comprising alternating current. In many embodiments, the electricity operating the one or more of switch(es) 105 can comprise the electricity provided by electricity source 103. Additionally, or alternatively, the electricity operating the one or more of switch(es) 105 can comprise other electricity being provided by another electricity source.

Further, control module 101 is configured so that when control module 101 causes inductive load module 104 to switch from the inactive state to the active state, the electricity is in the voltage zero crossing condition. Control module 101 is also configured so that when control module 101 causes inductive load module 104 to switch from the active state to the inactive state, the electricity is in the current zero crossing condition. Stated another way, control module 101 is configured (a) to control when inductive load module 104 begins receiving electricity from electricity supply 103 such that inductive load module 104 begins receiving electricity at approximately the same time as when the electricity is in the voltage zero crossing condition (or begins the voltage zero crossing condition) and (b) to control when inductive load module 104 stops receiving electricity from electricity supply 103 such that inductive load module 104 begins to stop receiving electricity at approximately the same time as when the electricity is in the current zero crossing condition (or begins the current zero crossing condition).

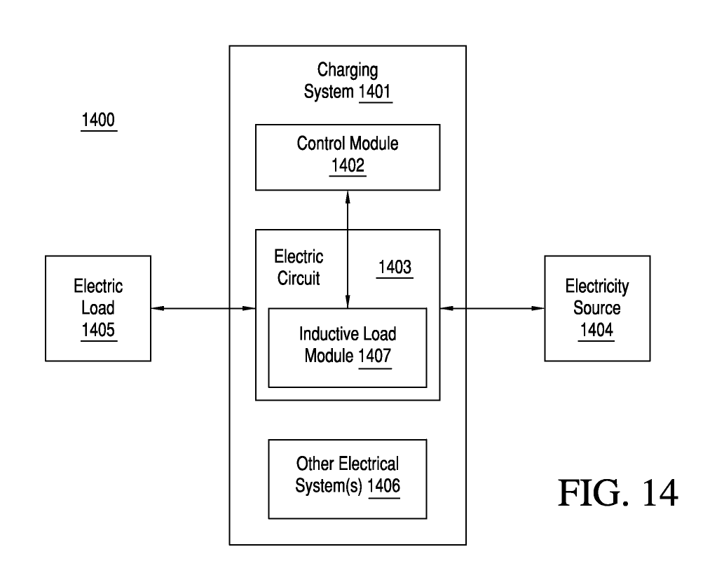

In many embodiments, after causing inductive load module 104 to switch to the active state, control module 101 can cause inductive load module 104 to maintain the active state (e.g., holding the active state through subsequent occurrences of the voltage zero crossing condition) until control module 101 determines otherwise. Likewise, after causing inductive load module 104 to switch to the inactive state, control module 101 can cause inductive load module 104 to maintain the inactive state (e.g., holding the inactive state through subsequent occurrences of the current zero crossing condition) until control module 101 determines otherwise. In these embodiments, control module 101 can determine when to cause inductive load module 104 to switch between the active and inactive states as dictated by a higher level system, such as, for example, a charging system and/or a computer system of the charging system. Such a charging system and/or computer system of the charging system can be similar or identical to charging system 1401 (FIG. 14) and/or the computer system described with respect to charging system 1401 (FIG. 14), as described below. Still, in other embodiments, control module 101 can cause inductive load module 104 to switch between the active and inactive states at each occurrence and/or at a predetermined occurrence (e.g., every second occurrence, etc.) of the voltage zero crossing and current zero crossing conditions.

Various advantages of timing the start and stop of the electricity to coincide with the voltage zero crossing condition and the current zero crossing condition in this manner are described next.

Specifically, by controlling when inductive load module 104 starts and stops receiving electricity from electricity source 103, control module 101 can mitigate and/or eliminate electric emissions and/or noise (e.g. transient noise) conducted and/or radiated by inductive load module 104. For example, where control module 101 is not implemented as part of system 100, the electric emissions and/or noise from inductive load module 104 can reach levels of greater than or equal to approximately 40 Megahertz and less than or equal to approximately 100 Megahertz. Meanwhile, in these or other examples, where control module 101 is implemented as part of system 100, the electric emissions and/or noise from inductive load module 104 that result when inductive load module 104 starts receiving electricity from electricity source 103 can be mitigated to approximately a 60 Hertz voltage spike of approximately 110% of a nominal voltage of (i) electric circuit 102 and/or (ii) another electronic device comprising electric circuit 102, such as, for example, a charging system, which can be similar or identical to charging system 1401 (FIG. 14); further, the electric emissions and/or noise from inductive load module 104 that result when inductive load module 104 stops receiving electricity from electricity source 103 can be mitigated to less than or equal to approximately 5% of an electric current spike at inductive load module 104 occurring in the absence of control module 101 being implemented. In these embodiments, the voltage spike can decay within approximately 1-2 cycles. Electric emissions and/or noise conducted and/or radiated by inductive load 104 can interfere with and/or damage electrical systems positioned around inductive load module 104 and/or electrical circuit 102, as explained further in the examples below.

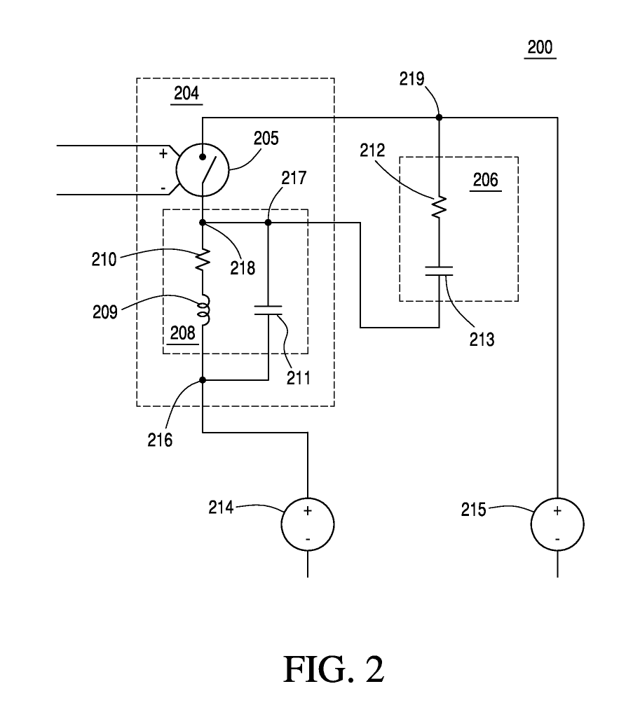

Turning to the next drawing, FIG. 2 illustrates electric circuit 200, according to an embodiment. More specifically, electric circuit 200 illustrates and/or models an exemplary embodiment of electric circuit 102 (FIG. 1) of system 100 (FIG. 1) to aid in illustrating the functionality of system 100 (FIG. 1) and, therefore, can be similar or identical to electric circuit 102 (FIG. 1). Accordingly, electric circuit 200 can comprise inductive load module 204, which can be similar or identical to inductive load module 104 (FIG. 1), and voltage transient suppression module 206, which can be similar or identical to voltage transient suppression module 106 (FIG. 1). Inductive load module 204 can comprise switch 205 (e.g., a relay) and inductive load 208. Switch 205 can be similar or identical to one of switch(es) 105 (FIG. 1). In some embodiments, such as, for example, where inductive load 208 is a contactor, inductive load 208 can comprise a large electrical inductance, a moderate electrical resistance, and a small parasitic capacitance. Thus, inductive load 208 (e.g., the contactor) can comprise and/or can be modeled as comprising inductor 209 (i.e., the large inductance), resistor 210 (i.e., the moderate resistance), and capacitor 211 (i.e., the small parasitic capacitance). The statement that inductor 209, resistor 210, and/or capacitor 211 model inductive load 208 is meant to indicate that inductive load 208 does not necessarily literally comprise inductor 209, resistor 210, and/or capacitor 211 but rather that inductor 209, resistor 210, and/or capacitor 211 can represent the intrinsic electrical inductance, electrical resistance, and parasitic capacitance of inductive load 208. For example, inductor 209 can comprise an inductance of greater than or equal to approximately 1-2 microHenries and less than or equal to approximately 1-200 Henries; resistor 210 can comprise a resistance of greater than or equal to approximately 10 Ohms and less than or equal to approximately 10,000 kiloOhms; and capacitor 211 can comprise a capacitance of greater than or equal to approximately 1-2 picoFarads and less than or equal to approximately 1-2 nanoFarads. In a specific example, inductor 209 can comprise an inductance of approximately 26 Henries; resistor 210 can comprise a resistance of approximately 4 Ohms; and capacitor 211 can comprise a capacitance of approximately 70 picoFarads. Meanwhile, voltage transient suppression module 206 can comprise resistor 212 and capacitor 213. For example, resistor 212 can comprise a resistance of greater than or equal to approximately 1 kiloOhm and less than or equal to approximately 1 MegaOhm; and capacitor 213 can comprise a capacitance of greater than or equal to approximately 10 picoFarads and less than or equal to approximately 1 microFarads. In a specific example, resistor 212 can comprise a resistance of approximately 15 Ohms; and capacitor 213 can comprise a capacitance of approximately 0.0047 microFarads. In many embodiments, the resistance of resistor 212 and/or the capacitance of capacitor 213 can depend on the inductance of inductor 209, the resistance of resistor 210, and/or the capacitance of capacitor 211. In other embodiments, voltage transient suppression module 206 can be omitted. Further, electric circuit 200 can comprise input 214 and output 215.

In many embodiments, inductor 209 and resistor 210 can be coupled in series with each other. Further, resistor 212 and capacitor 213 can be coupled in series with each other. Inductor 209, capacitor 211, and input 214 can be coupled at node 216. Resistor 210, switch 205, and capacitors 211 and 213 can be coupled at node 217. Switch 205, resistor 212, and output 215 can be coupled at node 219. Input 214 and output 215 can be coupled to an electricity source. The electricity source can be similar or identical to electricity source 103 (FIG. 1).

Meanwhile, inductive load module 204, switch 205, and/or inductive load 208 can be controlled by a control module. The control module can be similar or identical to control module 101 (FIG. 1). The following explains the manner in which electric circuit 200 operates with and without the control module, and thereby explains the manner in which electric circuit 102 operates with and without control module 101 (FIG. 1) by proxy.

Operating without the control module, when inductive load 208 first receives electricity from the electricity source coupled to input 214 and output 215 (e.g., when switch 205 is initially closed), no electric or magnetic energy is stored in electric circuit 200. Upon inductive load 208 first receiving the electricity from the electricity source, the parasitic capacitance (e.g., capacitor 211) of inductive load 208 can briefly provide a low-impedance path for electric current of the electricity to pass through inductive load 208. Where inductive load 208 first receives the electricity and an electric voltage develops at inductive load 208, an electric current of the electricity, having high-frequency components, can develop in electric circuit 102 (FIG. 1) and/or inductive load 208 while capacitor 211 charges. The higher the electric current and the frequency content thereof that is developed, the more likely the electrical emissions and/or noise are to interfere with and/or damage adjacent electrical systems.

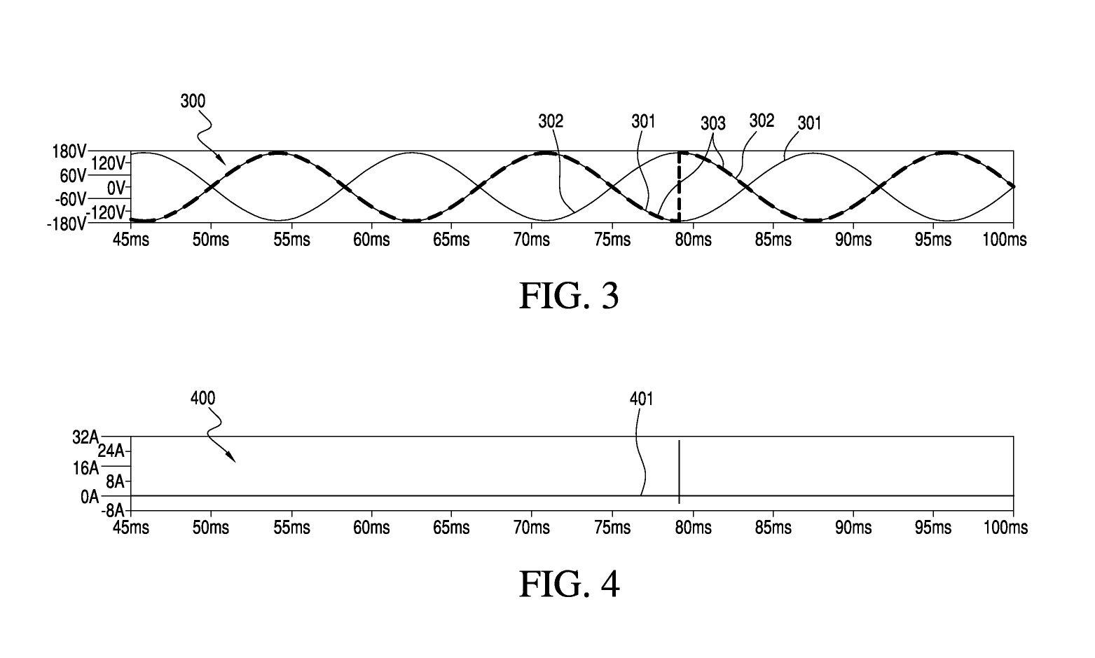

Turning ahead in the drawings, FIGS. 3 and 4 illustrate graphs 300 and 400 simulating a worst-case electric voltage and current scenario (i.e., the electric voltage resulting in the highest electric current) when inductive load 208 (FIG. 2) is receiving electricity and an electric voltage develops at inductive load 208 (FIG. 2). Graph 300 shows the line (e.g., mains line) voltages 301 and 302 from the electricity source and voltage 303 at inductive load 208 as a function of time. Voltage 303 is illustrated as a dashed line of thicker width than line voltages 301 and 302 to make clear when voltage 303 is overlapping line voltage 301 and/or line voltage 302. Voltage 303 can be seen shifting from being in phase with line voltage 301 to being in phase with line voltage 302. Meanwhile, graph 400 shows current 401 passing through switch 205 (FIG. 2) as a result of the varying voltages over time.

Returning to FIG. 2, when operating with the control module, by ensuring that inductive load 208 first receives electricity from the electricity source coupled to input 214 and output 215 when the electricity is in the voltage zero crossing condition, minimal to no electric voltage forms at capacitor 211, and thus, minimal to no current develops in electric circuit 102 (FIG. 1) and/or inductive load 208. In this manner, the control module can mitigate and/or eliminate interference and/or damage to adjacent electrical systems resulting from electricity initially provided to inductive load 208.

After the electricity passing through inductive load 208 stabilizes, inductor 209 can dominate inductive load 208 and/or capacitor 211 and store energy created by the steady-state electric current of the electricity flowing through inductive load 208 and/or inductor 209. Equation 1 provides the relationship of the energy (E) stored at inductor 209 as a function of the electric inductance (L) and current (I) at inductor 209.

E=0.5*L*I² (1)

Further, inductor 209 can resist changes in electric current passing there through, so suddenly stopping the electric current can result in a voltage surge. Equation 2 provides the relationship of the voltage (V) developed at inductor 209 as a function of the inductance (L) of inductor 209 and the change in the electric current (I) at inductor 209 with respect to time (t).

V=L*dI/dt (2)

As indicated by Equation 2, a sudden change in current can result in a voltage spike that can oscillate through inductive load 208 until the energy at inductor 209 dissipates. The resulting oscillation can also cause interference and/or damage to adjacent electrical systems.

In addition to the energy stored at inductor 209, there can also be energy stored at capacitor 211. Equation 3 provides the relationship of the energy (E) stored at capacitor 211 as a function of the capacitance (C) of capacitor 211 and the voltage at capacitor 211.

E=0.5*C*V² (3)

Similar to the energy at inductor 209, the energy stored at capacitor 211 can also oscillate through inductive load 208 and, thus, can also result in interference and/or damage to adjacent electrical systems. As illustrated by Equations 2 and 3, when inductive load 208 initially stops receiving electricity from the electricity source coupled to input 214 and output 215 (e.g., when switch 205 is initially opened), the voltage spike at inductor 209 is minimized where the electric current of the electricity is minimized, and the energy discharged by capacitor 211 is minimized where the electric voltage at capacitor 211 is minimized. However, in many examples, the current zero crossing condition of the electricity at inductor 209 and the voltage zero crossing condition of the electricity at capacitor 211 can be out of phase (e.g., 90 degrees out of phase), such that when one is minimized, the other is maximized. Nonetheless, because the energy at inductor 209 dominates the energy at capacitor 211 after the electricity at inductive load 208 stabilizes, as mentioned previously, the energy stored in inductor 209 can be approximately 100-1000 times greater than the energy stored in capacitor 211.

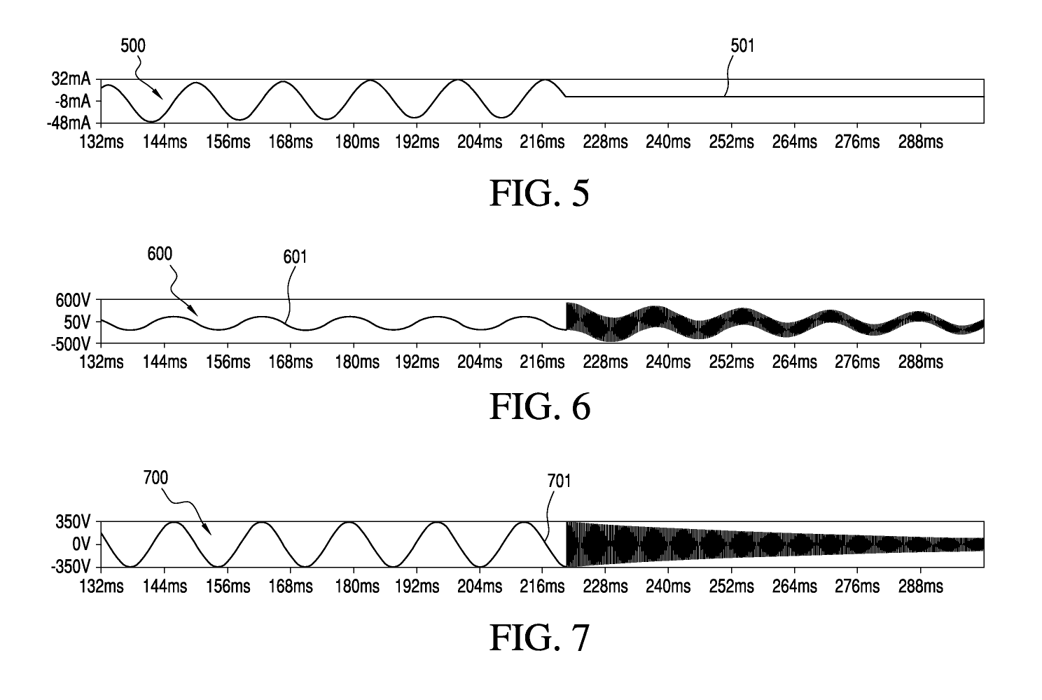

Turning ahead again in the drawings, FIGS. 5-7 illustrate graphs 500, 600, and 700 simulating when inductive load 208 (FIG. 2) initially stops receiving electricity from the electricity source and the electricity is in the current zero crossing condition, but omitting the effect of voltage transient suppression module 206 (FIG. 2). Specifically, graph 500 shows electric current 501 flowing through inductive load 208 (FIG. 2), as a function of time, when inductive load 208 (FIG. 2) initially stops receiving electricity from the electricity source and the electricity is in the current zero crossing condition; graph 600 shows electric voltage 601 at inductive load 208 (FIG. 2), as a function of time, when inductive load 208 (FIG. 2) initially stops receiving electricity from the electricity source and the electricity is in the current zero crossing condition; and graph 700 shows electric voltage 701 at capacitor 211 (FIG. 2), as a function of time, when inductive load 208 (FIG. 2) initially stops receiving electricity from the electricity source and the electricity is in the current zero crossing condition.

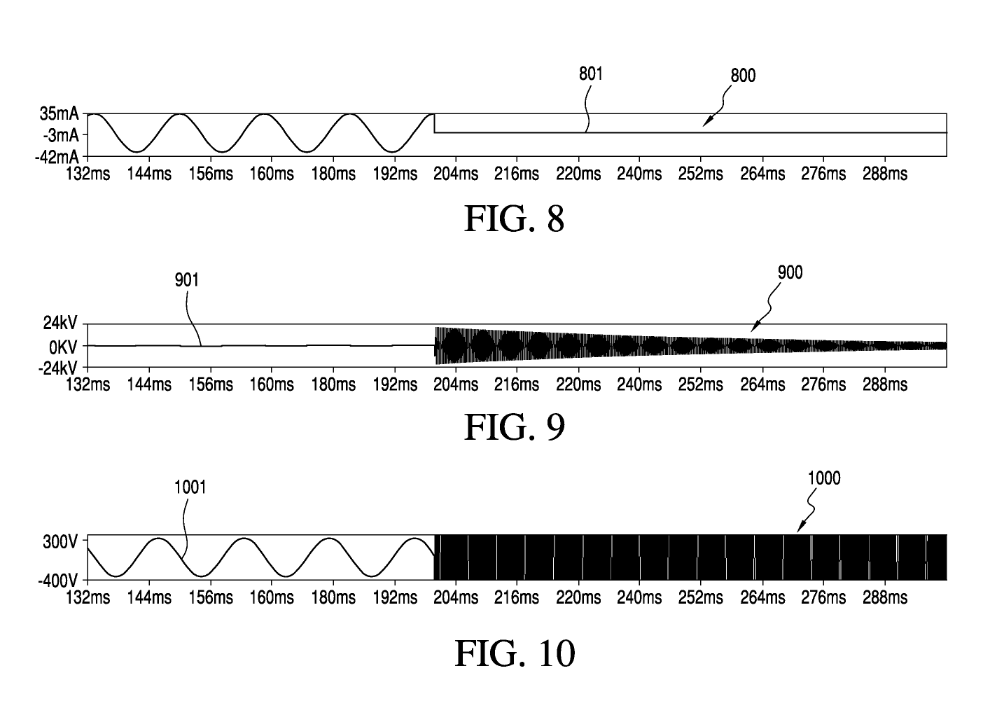

Meanwhile, FIGS. 8-10 illustrate graphs 800, 900, and 1000 simulating when inductive load 208 (FIG. 2) initially stops receiving electricity from the electricity source and the electricity is in the voltage zero crossing condition, but omitting the effect of voltage transient suppression module 206 (FIG. 2). Specifically, graph 800 shows electric current 801 flowing through inductive load 208 (FIG. 2), as a function of time, when inductive load 208 (FIG. 2) initially stops receiving electricity from the electricity source and the electricity is in the current zero crossing condition; graph 900 shows electric voltage 901 at inductive load 208 (FIG. 2), as a function of time, when inductive load 208 initially stops receiving electricity from the electricity source and the electricity is in the current zero crossing condition; and graph 1000 shows electric voltage 1001 at capacitor 211 (FIG. 2), as a function of time, when inductive load 208 initially stops receiving electricity from the electricity source and the electricity is in the current zero crossing condition. Thus, as illustrated at FIGS. 5-10, if only one of the current zero crossing condition or the voltage zero crossing condition can exist when inductive load 208 (FIG. 2) initially stops receiving electricity from the electricity source, the current zero crossing condition can result in greater reduction in electrical emissions and/or noise than the voltage zero crossing condition.

With reference again to FIG. 2, in light of the above, when the control module is implemented with electric circuit 200, the control module can ensure that inductive load 208 first stops receiving electricity from the electricity source coupled to input 214 and output 215 when the electricity is in the current zero crossing condition, minimizing the energy oscillating through electric circuit 200 and/or inductive load 208. If possible, the control module can ensure that inductive load 208 also stops receiving electricity from the electricity source couple to input 214 and output 215 when the electricity is in the voltage zero crossing condition (i.e., where the current zero crossing condition and the voltage zero crossing condition occur approximately simultaneously). In this manner, the control module can mitigate and/or eliminate interference and/or damage to adjacent electrical systems resulting from stopping providing electricity to inductive load 208.

In summary, the electrical emissions and/or noise emitted from inductive load 208 as a result of inductor 209 and capacitor 211 can be mitigated and/or eliminated by controlling when electricity starts and stops being received by inductive load 208. That is, if the control module times when electricity is initially provided to inductive load 208 with the voltage zero crossing condition of the electricity, an inrush of current can be mitigated or eliminated. Moreover, as the electric voltage of the electricity at capacitor 211 does increase, the electric voltage increases in proportion to the rate of change of the electric voltage of the electricity provided by the electricity source. Meanwhile, if the control module sets when electricity is initially stopped from being provided to inductive load 208 to occur at the current zero crossing condition of the electricity, minimal to no magnetic energy can be stored at inductor 209, and therefore, minimal to no voltage surge can result therefrom.

Nonetheless, as mentioned previously, because the current zero crossing condition of the electricity at inductor 209 and the voltage zero crossing condition of the electricity at capacitor 211 can be out of phase such that each occurs at different times, the energy stored capacitively at capacitor 211 can still cause an exponentially decaying oscillation to occur at electric circuit 200 and/or inductive load 208 even when the control module controls when inductive load 208 stops receiving electricity to coincide with when the electricity at inductive load 208 is in the current zero crossing condition. However, voltage transient suppression module 206 can operate to dampen the oscillation and/or voltage spikes that can result from capacitor 211, further mitigating and/or eliminating interference and/or damage to adjacent electrical systems resulting from stopping providing electricity to inductive load 208.

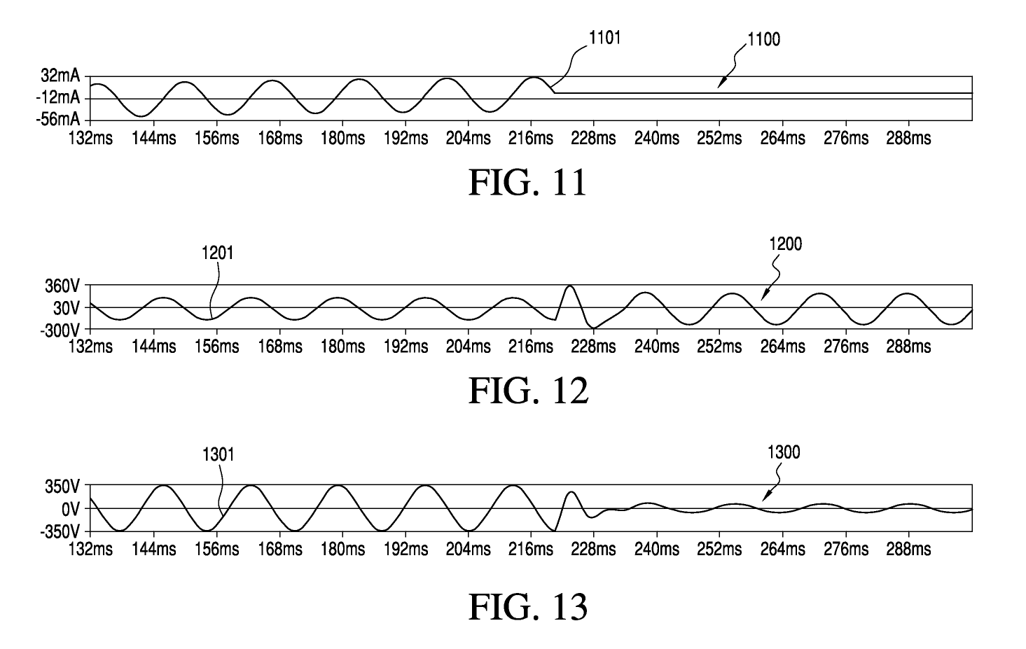

FIGS. 11-13 illustrates graphs 1100, 1200, and 1300 simulating when inductive load 208 initially stops receiving electricity from the electricity source and the electricity is in the current zero crossing condition, including the effect of voltage transient suppression module 206. Specifically, graph 1100 shows electric current 1101 flowing through inductive load 208, as a function of time, when inductive load 208 initially stops receiving electricity from the electricity source and the electricity is in the current zero crossing condition; graph 1200 shows electric voltage 1201 at inductive load 208, as a function of time, when inductive load 208 initially stops receiving electricity from the electricity source and the electricity is in the current zero crossing condition; and graph 1300 shows electric voltage 1301 at capacitor 211, as a function of time, when inductive load 208 initially stops receiving electricity from the electricity source and the electricity is in the current zero crossing condition.

In addition to or alternatively to implementing the control module to mitigate and/or eliminate electrical emissions and/or noise, other approaches can also be implemented to mitigate and/or eliminate electrical emissions and/or noise. Nonetheless, each of these other approaches can have drawbacks when compared to implementing the control module. For example, electrical systems can be positioned away from electric circuit 200 and/or inductive load module 204 such that electrical emissions and/or noise cannot reach the electrical systems. However, where device spatial volume is an issue, it may not be possible and/or desirable to position electrical systems away from electric circuit 200 and/or inductive load module 204. Meanwhile, (a) electrical systems and/or (b) electric circuit 200 and/or inductive load module 204 can be shielded to prevent electrical emissions and/or noise from the latter from interfering with and/or damaging the former. However, such an approach may again not be possible and/or desirable where device spatial volume is an issue. Further, electric filtering could be used to mitigate and/or eliminate electrical emissions and/or noise. However, filtering can require knowledge of the source of the electrical emissions and/or noise, which may not be known, constant, and/or readily predictable. Further still, inductive load module 204 can be customized for the specific system to mitigate and/or eliminate electrical emissions and/or noise. However, there may be few, if any, alternative embodiments for inductive load modules 204 that are configured to perform a desired functionality such that customization is difficult. Still, where possible, as indicated previously, one or more of these additional approaches can be used in conjunction with the control module to further reduce electrical emissions and/or noise. Yet another advantage of implementing the control module can be the ability to readily modify a device comprising electric circuit 200, such as, for example, to include other, more, and/or less electrical systems around and/or near to electric circuit 200.

Thus, the control module can improve the operation of electric circuit 200, and by proxy, control module 101 (FIG. 1) can improve the operation of electric circuit 102 (FIG. 1). Returning now to FIG. 1, the following further describes the implementation of control module 101.

Specifically, measurement module 107 can be configured to determine when the voltage and current zero crossing conditions of the electricity exist. Accordingly, control module 101 can be configured to communicate with measurement module 107 in order to determine when the zero voltage and current conditions of the electricity exist, and thereby to determine when to switch inductive load 104 from the inactive state to the active state, and vice versa. Measurement module 107 can comprise any suitable and/or conventional device(s) configured to measure the voltage and/or current of the electricity and/or time. Further, measurement module 107 can comprise any suitable and/or conventional device(s) configured to determine when the zero voltage and current conditions of the electricity exist. The device(s) implemented to determine when the zero voltage and current conditions of the electricity exist can depend upon a desired level of accuracy of determining the existence of the zero voltage and/or current conditions of the electricity.

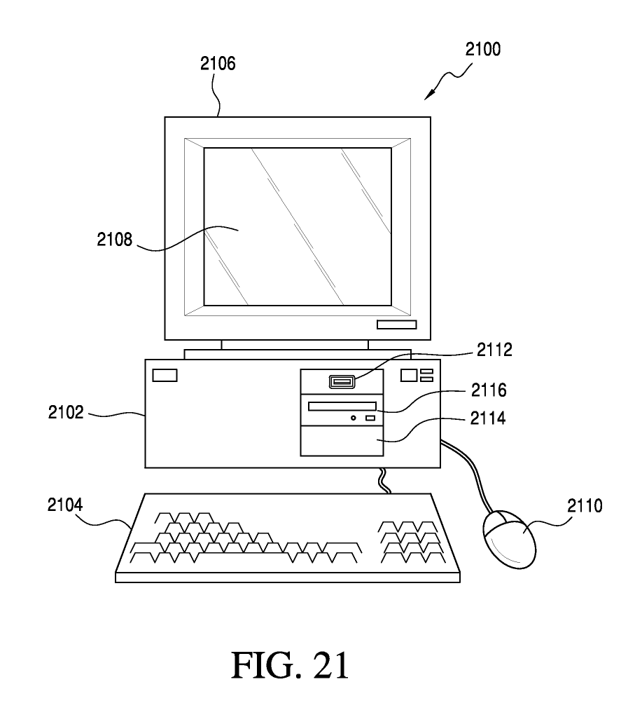

Control module 101 can be implemented as any suitable device(s) configured to control when inductive load module 104 receives electricity from electricity source 103. For example, control module 101 can be implemented as computer hardware and/or computer software. The computer hardware and/or computer software can be configured to operate switch(es) 105 to controllably complete and interrupt, or close or open, electric circuit 102 in the manner described above with respect to control module 101. Accordingly, in these embodiments, control module 101 can comprise a computer system. The computer system can be similar or identical to computer system 2100 (FIG. 21), as described below. In other examples, control module 101 can be implemented as an electromechanical device (e.g., an intrinsic thyristor) configured to control when inductive load module 104 receives electricity from electricity source 103.

In many embodiments, any suitable electrical system comprising an inductive load module (e.g., inductive load module 104) controlled by alternating current electricity can implement part or all of system 100 (e.g., control module 101, electric circuit 102, etc.). For example, such an electrical system can comprise a charging system, such as, for example, charging system 1401 (FIG. 14), as described below with respect to system 1400 (FIG. 14).

Turning ahead now in the drawings, FIG. 14 illustrates a block diagram of system 1400, according to an embodiment. System 1400 can comprise charging system 1401, control module 1402, and electric circuit 1403. In some embodiments, system 1400 can comprise electricity source 1404 and/or electric load 1405. Charging system 1401 can comprise control module 1402, electric circuit 1403, and/or one or more other electrical systems 1406. Further, electric circuit 1403 can comprise inductive load module 1407. Other electrical system(s) 1406 can be positioned around and/or near to electric circuit 1403 and/or inductive load module 1407.

In many embodiments, charging system 1401 can comprise a computer system. As described in greater detail below, the computer system can control charging system 1401. In many embodiments, the computer system can also comprise control module 1402. In other embodiments, the computer system and control module 1402 can be separate from each other. In other embodiments, the computer system can be omitted from system 1400.

In many embodiments, control module 1402 can be similar or identical to control module 101 (FIG. 1); electric circuit 1403 can be similar or identical to electric circuit 102 (FIG. 1) and/or electric circuit 200 (FIG. 2); electricity source 1404 can be similar or identical to electricity source 103 (FIG. 1); and/or inductive load module 1407 can be similar or identical to inductive load module 104 (FIG. 1) and/or inductive load module 204 (FIG. 2).

In many embodiments, electric circuit 1403 can be electrically coupled to electric load 1405 (e.g., via conductive and/or inductive coupling). Further, electric circuit 1403 can be coupled to electricity source 1404. Accordingly, electric circuit 1403 can receive electricity from electricity source 1404 and can provide the electricity to electric load 1405. In many examples, when electric circuit 1403 provides the electricity to electric load 1405 can be controlled by inductive load module 1407. For example, inductive load module 1407 can comprise a relay or a contactor configured to control when electric circuit 1403 receives electricity from electricity source 1404 (e.g., by the opening and closing of the relay or the contactor, as applicable). Meanwhile, electric circuit 1403 can be configured to provide electricity to electric load 1405 (e.g., to charge electric load 1405) when electric circuit 1403 receives electricity from electricity source 1404. Further, control module 1402 can control inductive load module 1407 (e.g., the relay or the contactor) to control the manner in which inductive load module 1407 controls when electric circuit 1403 receives electricity from electric source 1404. In many embodiments, control module 1402 can control inductive load module 1407 in a manner similar or identical to that described above with respect to control module 101 (FIG. 1) and inductive load module 104 (FIG. 1).

In more specific examples, charging system 1401 can comprise an electric vehicle charging station, and/or electric load 1405 can comprise a rechargeable energy storage system of an electric vehicle. Accordingly, charging system 1401 (e.g., the electric vehicle charging station) can be configured to provide electricity from electricity source 1404 to electric load 1405 (e.g., the rechargeable energy storage system) via electric circuit 1403 in order to charge electric load 1405.

The electric vehicle charging station can comprise any suitable alternating current and/or direct current electric vehicle supply equipment. For example, the electric vehicle charging station can comprise electric vehicle supply equipment configured according to any one of the Society of Automotive Engineers (SAE) International electric vehicle supply equipment standards (e.g., Level 1, Level 2, and/or Level 3) and/or the International Electrotechnical Commission (IEC) standards (e.g., Mode 1, Mode 2, Mode 3, and/or Mode 4).

Further, the rechargeable energy storage system can be configured to provide electricity to the electric vehicle comprising the rechargeable energy storage system to provide motive (e.g., traction) electrical power to the electric vehicle and/or to provide electricity to any electrically operated components of the electric vehicle. In some embodiments, the rechargeable energy storage system can comprise an electricity transfer rating of greater than or equal to approximately (⅛)C (e.g., approximately (¼)C, approximately (⅓)C, approximately (½)C, approximately 1C, approximately 2C, approximately 3C, etc.), where the electricity transfer rating refers to an electricity charge and/or discharge rating of the rechargeable energy storage system in terms of the electric current capacity of the rechargeable energy storage system in ampere-hours. Further, the rechargeable energy storage system can comprise an electric energy storage capacity of greater than or equal to approximately 1 kiloWatt-hour (kW-hr). For example, the rechargeable energy storage system can comprise an electric energy storage capacity of greater than or equal to approximately 20 kW-hrs and less than or equal to approximately 50 kW-hrs. In further examples, the rechargeable energy storage system can comprise an electric energy storage capacity of greater than or equal to approximately 5 kW-hrs and less than or equal to approximately 100 kW-hrs.

In specific examples, the rechargeable energy storage system can comprise (a) one or more batteries and/or one or more fuel cells, (b) one or more capacitive energy storage systems (e.g., super capacitors such as electric double-layer capacitors), and/or (c) one or more inertial energy storage systems (e.g., one or more flywheels). In many embodiments, the one or more batteries can comprise one or more rechargeable and/or non-rechargeable batteries. For example, the one or more batteries can comprise one or more lead-acid batteries, valve regulated lead acid (VRLA) batteries such as gel batteries and/or absorbed glass mat (AGM) batteries, nickel-cadmium (NiCd) batteries, nickel-zinc (NiZn) batteries, nickel metal hydride (NiMH) batteries, zebra (e.g., molten chloroaluminate (NaAlCl₄)) batteries, and/or lithium (e.g., lithium-ion (Li-ion)) batteries.

Further, the electric vehicle can comprise any full electric vehicle, any hybrid vehicle, and/or any other grid-connected vehicle. In the same or different embodiments, the electric vehicle can comprise any one of a car, a truck, motorcycle, a bicycle, a scooter, a boat, a train, an aircraft, an airport ground support equipment, and/or a material handling equipment (e.g., a fork-lift), etc.

As mentioned previously, charging system 1401 can comprise a computer system configured to control charging system 1401. That is, charging system 1401 can comprise a smart charging system. In other embodiments, the computer system can be omitted, and charging system 1401 can be operated manually. In any event, control module 1402 and/or the functionality of control module 1402 can be subordinate to the overall control of charging system 1401 by the computer system and/or by manual operation. For example, at a higher level, a determination can be made, by the computer system and/or by manual operation, regarding whether charging system 1401 and/or electric circuit 1403 should make electricity from electricity source 1404 available to electric load 1405. Then, at a lower level, control module 1402 can control when the electricity from electricity source 1404 is provided to electric circuit 1403 and/or inductive load module 1407, as described above with respect to control module 101 (FIG. 1) and electric circuit 102 (FIG. 1).

By implementing control module 1402 at system 1400 and/or charging system 1401, control module 1402 can mitigate and/or eliminate electric emissions and/or noise emitted by electric circuit 1403 and/or inductive load module 1407, thereby also mitigating and/or eliminating interference and/or damage to other electrical system(s) 1406. Other electrical system(s) 1406 can comprise any suitable electrical system(s), such as, for example, one or more electrical systems related to electric vehicle charging. For example, other electrical system(s) 1406 can comprise a residual-current circuit breaker (e.g., a ground fault circuit interrupter), any suitable communication device, such as, for example, a radio frequency identification device, a wired and/or wireless networking device, a bus connector (e.g., a Universal Serial Bus connector, etc.), an energy meter, etc.). As indicated above, exposure to such electrical emissions and/or noise by other electrical system(s) 1406 can interfere with and/or damage other electrical system(s) 1406.

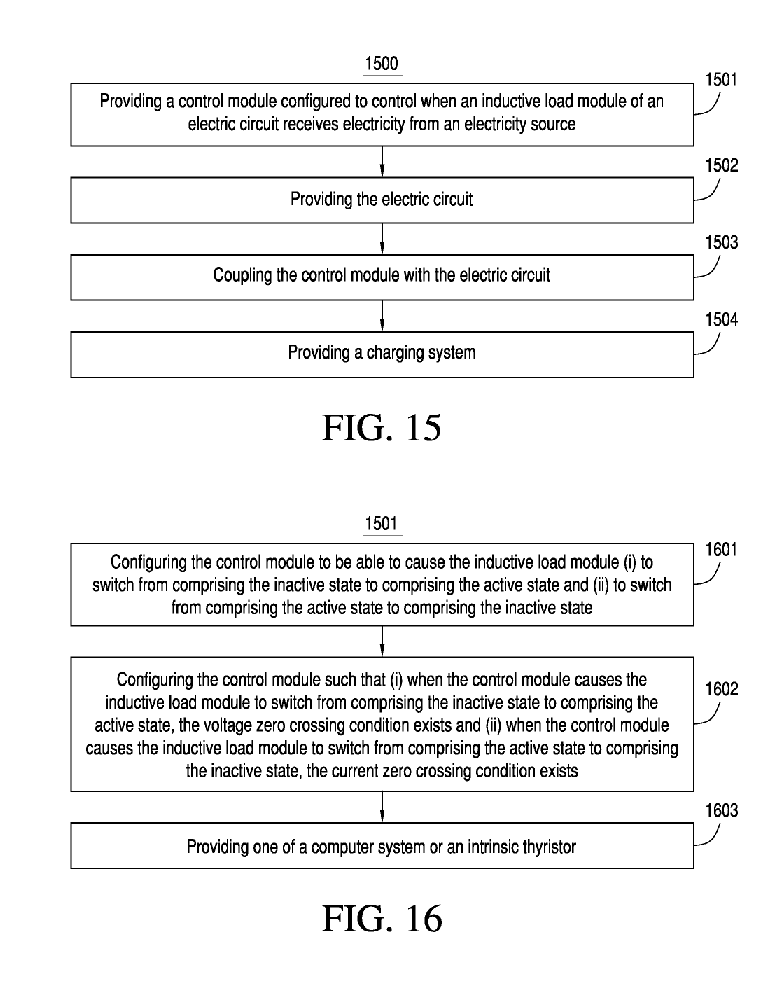

Turning to the drawings, FIG. 15 illustrates a flow chart for an embodiment of method 1500 of manufacturing a system. Method 1500 is merely exemplary and is not limited to the embodiments presented herein. Method 1500 can be employed in many different embodiments or examples not specifically depicted or described herein. In some embodiments, the procedures, the processes, and/or the activities of method 1500 can be performed in the order presented. In other embodiments, the procedures, the processes, and/or the activities of method 1500 can be performed in any other suitable order. In still other embodiments, one or more of the procedures, the processes, and/or the activities in method 1500 can be combined or skipped. The system can be similar or identical to system 100 (FIG. 1) and/or system 1400 (FIG. 14).

Method 1500 can comprise activity 1501 of providing a control module configured to control when an inductive load module of an electric circuit receives electricity from an electricity source. The control module can be similar or identical to control module 101 (FIG. 1), control module 1402 (FIG. 14), and/or the control module described above with respect to electric circuit 200 (FIG. 2). Further, the inductive load module can be similar or identical to inductive load module 104 (FIG. 1), inductive load module 204 (FIG. 2), and/or inductive load module 1407 (FIG. 14); the electric circuit can be similar or identical to electric circuit 102 (FIG. 1), electric circuit 200 (FIG. 2), and/or electric circuit 1403 (FIG. 14); and/or the electricity source can be similar or identical to electricity source 103 (FIG. 1), electricity source 1404 (FIG. 14), and/or the electricity source described above with respect to electric circuit 200 (FIG. 2). FIG. 16 illustrates an exemplary activity 1501.

Referring to FIG. 16, activity 1501 can comprise activity 1601 of configuring the control module to be able to cause the inductive load module (i) to switch from the inactive state to the active state and (ii) to switch from the active state to the inactive state. The active state and the inactive state can be similar or identical to the active state and the inactive state described above with respect to system 100 (FIG. 1).

Further, activity 1501 can comprise activity 1602 of configuring the control module such that (i) when the control module causes the inductive load module to switch from the inactive state to the active state, the voltage zero crossing condition exists and (ii) when the control module causes the inductive load module to switch from the active state to the inactive state, the current zero crossing condition exists. The voltage zero crossing condition and the current zero crossing condition can be similar or identical to the voltage zero crossing condition and the current zero crossing condition described above with respect to system 100 (FIG. 1).

Activity 1501 can also comprise activity 1603 of providing one of a computer system or an intrinsic thyristor. The computer system and/or the intrinsic thyristor can be similar or identical to the computer system and/or intrinsic thyristor described above with respect to system 100 (FIG. 1). In some embodiments, two or more of activities 1601 through 1603 can be performed approximately simultaneously.

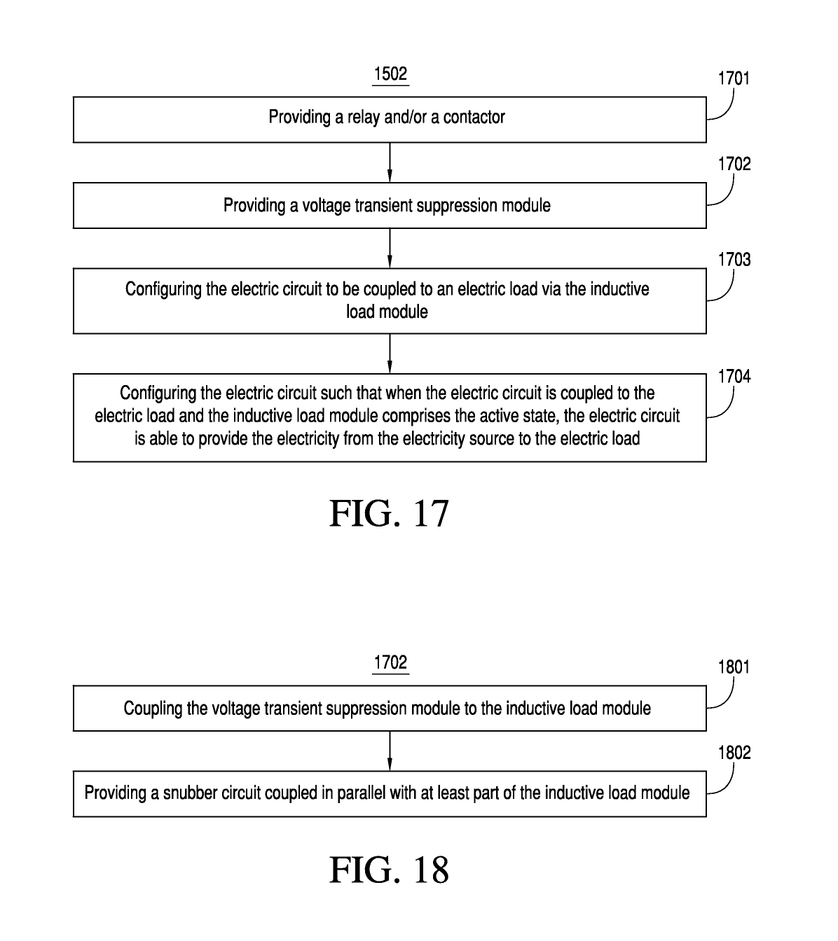

Returning now to FIG. 15, method 1500 can comprise activity 1502 of providing the electric circuit. In some embodiments, activity 1502 can be omitted. FIG. 17 illustrates an exemplary activity 1502.

Skipping ahead to FIG. 17, activity 1502 can comprise activity 1701 of providing a relay and/or a contactor. The inductive load module can comprise the relay and/or the contactor. Further, the relay and/or contactor can be similar or identical to the relay and/or contactor described above with respect to system 100 (FIG. 1), system 1400 (FIG. 14), and/or switch 205 (FIG. 2).

Activity 1502 can also comprise activity 1702 of providing a voltage transient suppression module. The voltage transient suppression module can be similar or identical to voltage transient suppression module 106 (FIG. 1) and/or voltage transient suppression module 206 (FIG. 2). In some embodiments, activity 1702 can be omitted. FIG. 18 illustrates an exemplary activity 1702.

Turning forward to FIG. 18, activity 1702 can comprise activity 1801 of coupling the voltage transient suppression module to the inductive load module. In many embodiments, activity 1801 can comprise coupling the voltage transient suppression module in parallel with the inductive load module.

Activity 1702 can also comprise activity 1802 of providing a snubber circuit coupled in parallel with at least part of the inductive load module. In many embodiments, the voltage transient suppression module can comprise the snubber circuit. The snubber circuit can be similar or identical to the snubber circuit described above with respect to system 100 (FIG. 1). In some embodiments, activity 1801 and/or activity 1802 can be omitted.

Returning now to FIG. 17, activity 1502 can also comprise activity 1703 of configuring the electric circuit to be coupled to an electric load via the inductive load module. The electric load can be similar or identical to electric load 1405 (FIG. 14). In some embodiments, activity 1703 can comprise configuring the electric circuit to be coupled to a rechargeable energy storage system of an electric vehicle via the inductive load module. In many embodiments, the rechargeable energy storage system and/or the electric vehicle can be similar or identical to the rechargeable energy storage system and/or the electric vehicle described above with respect to system 1400 (FIG. 14).

Activity 1502 can further comprise activity 1704 of configuring the electric circuit such that when the electric circuit is coupled to the electric load and the inductive load module comprises the active state, the electric circuit is able to permit the electricity to be provided from the electricity source to the electric load. In some embodiments, activity 1703 and/or activity 1704 can be omitted.

Returning now to FIG. 15, method 1500 can also comprise activity 1503 of coupling the control module with the electric circuit.

In some embodiments, method 1500 can further comprise activity 1504 of providing a charging system (e.g., an electric vehicle charging station). The charging system can be similar or identical to charging system 1401 (FIG. 14). Accordingly, the charging system can comprise the electric circuit and/or the control module. In some embodiments, activity 1503 and/or activity 1504 can be omitted.

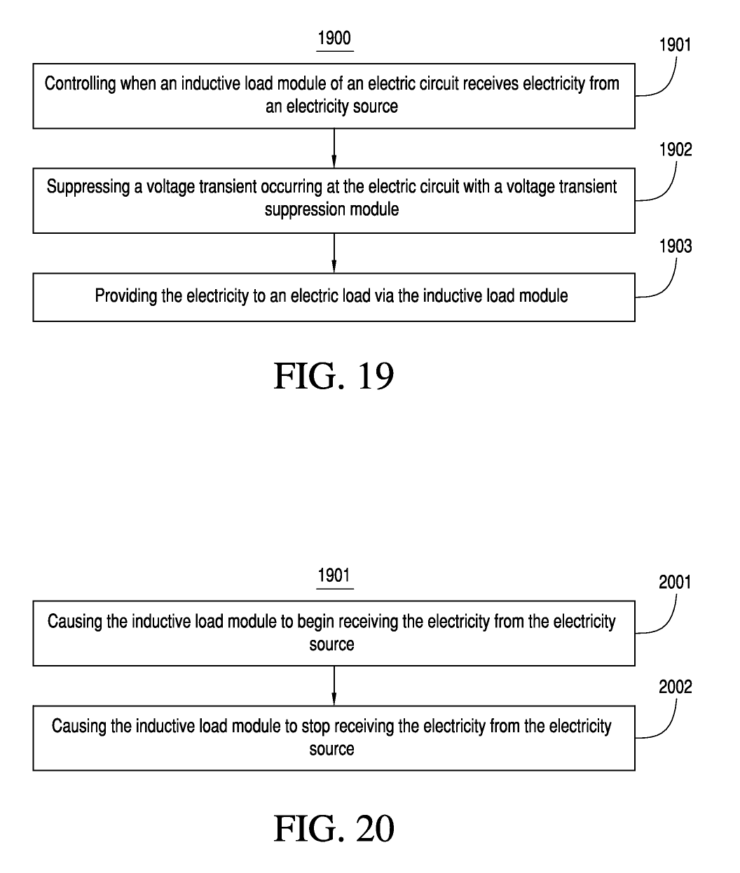

FIG. 19 illustrates a flow chart for an embodiment of method 1900. Method 1900 is merely exemplary and is not limited to the embodiments presented herein. Method 1900 can be employed in many different embodiments or examples not specifically depicted or described herein. In some embodiments, the procedures, the processes, and/or the activities of method 1900 can be performed in the order presented. In other embodiments, the procedures, the processes, and/or the activities of method 1900 can be performed in any other suitable order. In still other embodiments, one or more of the procedures, the processes, and/or the activities in method 1900 can be combined or skipped. In many embodiments, method 1900 can be implemented as one or more computer instructions configured to be run at one or more processing module and stored at one or more memory storage modules of a computer system. The computer system can be similar or identical to computer system 2100 (FIG. 21). Further, the computer system can be similar or identical to control module 101 (FIG. 1), control module 1402 (FIG. 14), and/or the control module described above with respect to electric circuit 200 (FIG. 2).

Method 1900 can comprise activity 1901 of controlling when an inductive load module of an electric circuit receives electricity from an electricity source. The inductive load module can be similar or identical to inductive load module 104 (FIG. 1), inductive load module 204 (FIG. 2), and/or inductive load module 1407 (FIG. 14); the electric circuit can be similar or identical to electric circuit 102 (FIG. 1), electric circuit 200 (FIG. 2), and/or electric circuit 1403 (FIG. 14); and/or the electricity source can be similar or identical to electricity source 103 (FIG. 1), electricity source 1404 (FIG. 14), and/or the electricity source described above with respect to electric circuit 200 (FIG. 2). FIG. 20 illustrates an exemplary activity 1901.

Referring now to FIG. 20, activity 1901 can comprise activity 2001 of causing the inductive load module to begin receiving the electricity from the electricity source. The electricity can comprise alternating current. In many embodiments, activity 2001 can occur when the voltage zero crossing condition exists. The voltage zero crossing condition can be similar or identical to the voltage zero crossing condition described above with respect to system 100 (FIG. 1). In various embodiments, activity 2001 can comprise closing a relay and/or a contactor. The relay and/or contactor can be similar or identical to the relay and/or contactor described above with respect to system 100 (FIG. 1), system 1400 (FIG. 14), and/or switch 205 (FIG. 2). The inductive load module can comprise the relay and/or the contactor. In some embodiments, activity 2001 can comprise receiving a start instruction indicating that the inductive load module is to receive electricity from the electricity source, and/or causing the inductive load module to receive the electricity from the electricity source while or after the voltage zero crossing condition exists or begins, such as, for example, until receiving a stop instruction. Receiving the start instruction and/or the stop instruction can occur at a charging system and/or a computer system of the charging system. The charging system can be similar or identical to charging system 1401 (FIG. 14), and/or the computer system can be similar or identical to the computer system described above with respect to charging system 1401 (FIG. 14). Receiving the start instruction and/or stop instruction can be similar or identical to the manner to the higher and lower level command structure described above with respect to system 1400 (FIG. 14) and/or charging system 1401 (FIG. 14).

Activity 1901 can also comprise activity 2002 of causing the inductive load module to stop receiving the electricity from the electricity source. In many embodiments, activity 2001 can occur when the current zero crossing condition exists. The current zero crossing condition can be similar or identical to the current zero crossing condition described above with respect to system 100 (FIG. 1). Further, activity 2002 can occur after activity 2001. In various embodiments, activity 2002 can comprise opening the relay and/or the contactor.

Returning to FIG. 19, method 1900 can further comprise activity 1902 of suppressing a voltage transient occurring at the electric circuit with a voltage transient suppression module. The voltage transient suppression module can be similar or identical to voltage transient suppression module 106 (FIG. 1) and/or voltage transient suppression module 206 (FIG. 2). Activity 1902 can occur approximately simultaneously and/or after activity 2002. In many embodiments, activity 1901 and activity 1902 can be repeated one or more times.

Method 1900 can also comprise activity 1903 of providing the electricity to an electric load via the inductive load module. Activity 1903 can be performed approximately simultaneously with and/or after activity 2001 and before activity 2002. Further, activity 1903 can comprise providing the electricity to a rechargeable energy storage system of an electric vehicle. The electric vehicle can comprise the rechargeable energy storage system. Meanwhile, the electric load can also comprise the rechargeable energy storage system. The electric load can be similar or identical to electric load 1405 (FIG. 14). In many embodiments, the rechargeable energy storage system and/or the electric vehicle can be similar or identical to the rechargeable energy storage system and/or the electric vehicle described above with respect to system 1400 (FIG. 14).

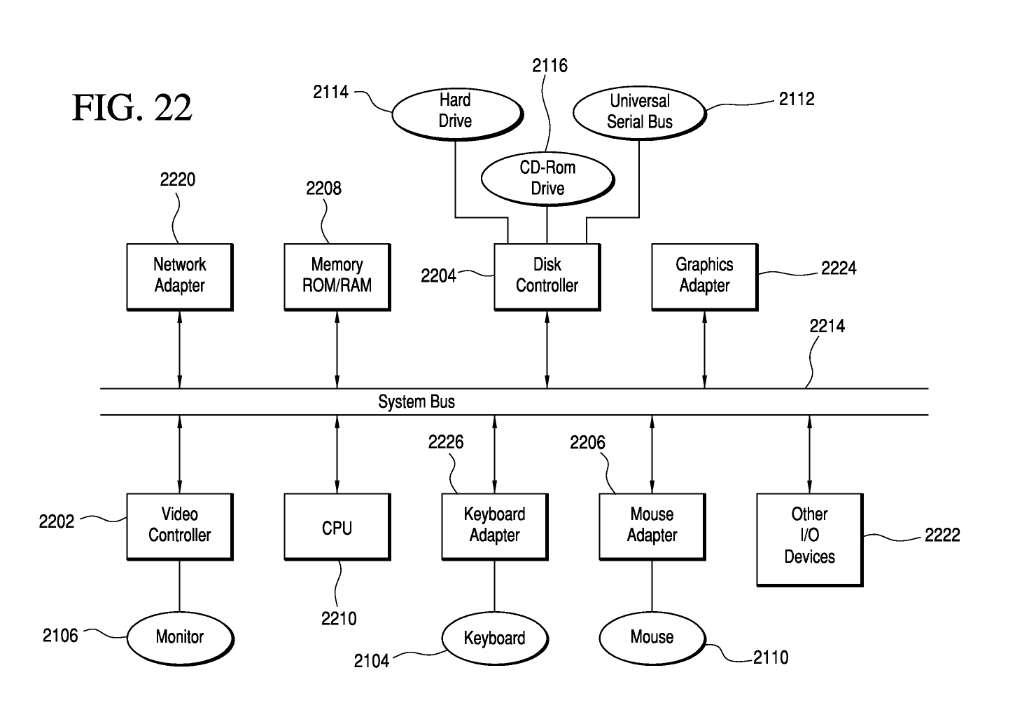

Turning ahead again in the drawings, FIG. 21 illustrates an exemplary embodiment of computer system 2100, all of which or a portion of which can be suitable for implementing an embodiment of control module 101 (FIG. 1), control module 1402 (FIG. 14), the computer system described above with respect to charging system 1401 (FIG. 14), and/or any of various other elements of system 100 (FIG. 1) and/or system 1400 (FIG. 14) as well as any of the various procedures, processes, and/or activities of method 1500 (FIG. 14) and/or method 1900 (FIG. 19). As an example, a different or separate one of chassis 2102 (and its internal components) can be suitable for implementing control module 101 (FIG. 1), control module 1402 (FIG. 14), and/or the computer system described above with respect to charging system 1401 (FIG. 14), etc. Computer system 2100 comprises chassis 2102 containing one or more circuit boards (not shown), Universal Serial Bus (USB) port 2112, Compact Disc Read-Only Memory (CD-ROM) and/or Digital Video Disc (DVD) drive 2116, and hard drive 2114. A representative block diagram of the elements included on the circuit boards inside chassis 1202 is shown in FIG. 22. Central processing unit (CPU) 2210 in FIG. 22 is coupled to system bus 2214 in FIG. 22. In various embodiments, the architecture of CPU 2210 can be compliant with any of a variety of commercially distributed architecture families.

Continuing with FIG. 22, system bus 2214 also is coupled to memory storage unit 2208, where memory storage unit 2208 comprises both read only memory (ROM) and random access memory (RAM). Non-volatile portions of memory storage unit 2208 or the ROM can be encoded with a boot code sequence suitable for restoring computer system 2100 (FIG. 21) to a functional state after a system reset. In addition, memory storage unit 2208 can comprise microcode such as a Basic Input-Output System (BIOS). In some examples, the one or more memory storage units of the various embodiments disclosed herein can comprise memory storage unit 2208, a USB-equipped electronic device, such as, an external memory storage unit (not shown) coupled to universal serial bus (USB) port 2112 (FIGS. 21-22), hard drive 2114 (FIGS. 21-22), and/or CD-ROM or DVD drive 2116 (FIGS. 21-22). In the same or different examples, the one or more memory storage units of the various embodiments disclosed herein can comprise an operating system, which can be a software program that manages the hardware and software resources of a computer and/or a computer network. The operating system can perform basic tasks such as, for example, controlling and allocating memory, prioritizing the processing of instructions, controlling input and output devices, facilitating networking, and managing files. Some examples of common operating systems can comprise Microsoft® Windows® operating system (OS), Mac® OS, UNIX® OS, and Linux® OS.

As used herein, “processor” and/or “processing module” means any type of computational circuit, such as but not limited to a microprocessor, a microcontroller, a controller, a complex instruction set computing (CISC) microprocessor, a reduced instruction set computing (RISC) microprocessor, a very long instruction word (VLIW) microprocessor, a graphics processor, a digital signal processor, or any other type of processor or processing circuit capable of performing the desired functions. In some examples, the one or more processors of the various embodiments disclosed herein can comprise CPU 2210.

In the depicted embodiment of FIG. 22, various I/O devices such as disk controller 2204, graphics adapter 2224, video controller 2202, keyboard adapter 2226, mouse adapter 2206, network adapter 2220, and other I/O devices 2222 can be coupled to system bus 2214. Keyboard adapter 2226 and mouse adapter 2206 are coupled to keyboard 2104 (FIGS. 21-22) and mouse 2110 (FIGS. 21-22), respectively, of computer system 2100 (FIG. 21). While graphics adapter 2224 and video controller 2202 are indicated as distinct units in FIG. 22, video controller 2202 can be integrated into graphics adapter 2224, or vice versa in other embodiments. Video controller 2202 is suitable for refreshing monitor 2106 (FIGS. 21-22) to display images on a screen 2108 (FIG. 21) of computer system 2100 (FIG. 21). Disk controller 2204 can control hard drive 2114 (FIGS. 21-22), USB port 2112 (FIGS. 21-22), and CD-ROM drive 2116 (FIGS. 21-22). In other embodiments, distinct units can be used to control each of these devices separately.

In some embodiments, network adapter 2220 can comprise and/or be implemented as a WNIC (wireless network interface controller) card (not shown) plugged or coupled to an expansion port (not shown) in computer system 2100 (FIG. 21). In other embodiments, the WNIC card can be a wireless network card built into computer system 2100 (FIG. 21). A wireless network adapter can be built into computer system 2100 by having wireless communication capabilities integrated into the motherboard chipset (not shown), or implemented via one or more dedicated wireless communication chips (not shown), connected through a PCI (peripheral component interconnector) or a PCI express bus of computer system 2100 (FIG. 21) or USB port 2112 (FIG. 21). In other embodiments, network adapter 2220 can comprise and/or be implemented as a wired network interface controller card (not shown).

Although many other components of computer system 2100 (FIG. 21) are not shown, such components and their interconnection are well known to those of ordinary skill in the art. Accordingly, further details concerning the construction and composition of computer system 2100 and the circuit boards inside chassis 2102 (FIG. 21) are not discussed herein.

When computer system 2100 in FIG. 21 is running, program instructions stored on a USB-equipped electronic device connected to USB port 2112, on a CD-ROM or DVD in CD-ROM and/or DVD drive 2116, on hard drive 2114, or in memory storage unit 2208 (FIG. 22) are executed by CPU 2210 (FIG. 22). A portion of the program instructions, stored on these devices, can be suitable for carrying out at least part of control module 101 (FIG. 1), control module 1402 (FIG. 14), the computer system described above with respect to charging system 1401 (FIG. 14), and/or any of various other elements of system 100 (FIG. 1) and/or system 1400 (FIG. 14) as well as any of the various procedures, processes, and/or activities of method 1500 (FIG. 14) and/or method 1900 (FIG. 19).

Although computer system 2100 is illustrated as a desktop computer in FIG. 21, there can be examples where computer system 2100 may take a different form factor while still having functional elements similar to those described for computer system 2100. In some embodiments, computer system 2100 may comprise a single computer, a single server, or a cluster or collection of computers or servers, or a cloud of computers or servers. Typically, a cluster or collection of servers can be used when the demand on computer system 2100 exceeds the reasonable capability of a single server or computer.

Meanwhile, in some embodiments, control module 101 (FIG. 1), control module 1402 (FIG. 14), the computer system described above with respect to charging system 1401 (FIG. 14) can have only those processing capabilities and/or memory storage capabilities as are reasonably necessary to perform the functionality, described above with respect to system 100 (FIG. 1) and/or system 1400 (FIG. 14). In a more detailed example, control module 101 (FIG. 1), control module 1402 (FIG. 14), the computer system described above with respect to charging system 1401 (FIG. 14) could be implemented as a microcontroller comprising flash memory, or the like. Reducing the sophistication and/or complexity of any of control module 101 (FIG. 1), control module 1402 (FIG. 14), the computer system described above with respect to charging system 1401 (FIG. 14) can reduce the size and/or cost of implementing control module 101 (FIG. 1), control module 1402 (FIG. 14), the computer system described above with respect to charging system 1401 (FIG. 14). Nonetheless, in other embodiments, control module 101 (FIG. 1), control module 1402 (FIG. 14), the computer system described above with respect to charging system 1401 (FIG. 14) may need additional sophistication and/or complexity to operate as desired.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that activities 1501-1504 of FIG. 15, activities 1601-1603 of FIG. 16, activities 1701-1704 of FIG. 17, activities 1801-1802 of FIG. 18, activities 1901-1903 of FIG. 19, and/or activities 2001-2002 of FIG. 20 may be comprised of many different procedures, processes, and activities and be performed by many different modules, in many different orders, that any element of FIGS. 1-22 may be modified, and that the foregoing discussion of certain of these embodiments does not necessarily represent a complete description of all possible embodiments.

All elements claimed in any particular claim are essential to the embodiment claimed in that particular claim. Consequently, replacement of one or more claimed elements constitutes reconstruction and not repair. Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims, unless such benefits, advantages, solutions, or elements are expressly stated in such claim.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1) A system comprising:
a control module configured to control when an inductive load module of an electric circuit receives electricity from an electricity source, the electric circuit (a) comprising the inductive load module and (b) being configured to be coupled to the electricity source;
wherein:
when the control module permits the inductive load module to receive the electricity from the electricity source, the inductive load module comprises an active state;
when the control module prevents the inductive load module from receiving the electricity from the electricity source, the inductive load module comprises an inactive state;
the electricity comprises a voltage zero crossing condition and a current zero crossing condition; and
in order to control when the inductive load module of the electric circuit receives the electricity from the electricity source:
(a) the control module is configured to be able to cause the inductive load module (i) to switch from the inactive state to the active state and (ii) to switch from the active state to the inactive state; and
(b) the control module is further configured such that (i) when the control module causes the inductive load module to switch from the inactive state to the active state, the voltage zero crossing condition exists or is starting and (ii) when the control module causes the inductive load module to switch from the active state to the inactive state, the current zero crossing condition exists or is starting.

2) The system of claim 1 wherein:
the inductive load module comprises at least one of a relay or a contactor.

3) The system of claim 1 wherein:
the electric circuit comprises a voltage transient suppression module coupled to the inductive load module.

4) The system of claim 3 wherein:
the voltage transient suppression module comprises a snubber circuit coupled in parallel with at least part of the inductive load module.

5) The system of claim 1 wherein:
the control module comprises one of a computer system or an intrinsic thyristor.

6) The system of claim 1 wherein:
the system further comprises the electric circuit.

7) The system of claim 1 wherein:
the electric circuit is configured to be coupled to an electric load via the inductive load module; and
when the electric circuit is coupled to the electric load and the inductive load module comprises the active state, the electric circuit is configured to permit the electricity to be conducted from the electricity source to the electric load.

8) The system of claim 7 wherein:
the electric load comprises a rechargeable energy storage system of an electric vehicle, the electric vehicle comprising the rechargeable energy storage system.

9) The system of claim 1 further comprising:
an electric vehicle charging station, the electric vehicle charging station comprising at least one of the electric circuit or the control module.

10) The system of claim 1 wherein:
the control module is configured to mitigate electric noise in the electric circuit.

11) A method of manufacturing a system, the method comprising:
providing a control module configured to control when an inductive load module of an electric circuit receives electricity from an electricity source, the electric circuit (a) comprising the inductive load module and (b) being configured to be coupled to the electricity source;
wherein:
when the control module permits the inductive load module to receive the electricity from the electricity source, the inductive load module comprises an active state;
when the control module prevents the inductive load module from receiving the electricity from the electricity source, the inductive load module comprises an inactive state;
the electricity comprises a voltage zero crossing condition and a current zero crossing condition; and
providing the control module comprises:
(a) configuring the control module to be able to cause the inductive load module (i) to switch from the inactive state to the active state and (ii) to switch from the active state to the inactive state; and
(b) configuring the control module such that (i) when the control module causes the inductive load module to switch from the inactive state to the active state, the voltage zero crossing condition exists or is starting and (ii) when the control module causes the inductive load module to switch from the active state to the inactive state, the current zero crossing condition exists or is starting.

12) The method of claim 11 further comprising:
providing the electric circuit; and
coupling the control module with the electric circuit.

13) The method of claim 12 wherein:
providing the electric circuit comprises providing at least one of a relay or a contactor, the inductive load module comprising the at least one of the relay or the contactor.

14) The method of claim 12 wherein:
providing the electric circuit comprises providing a voltage transient suppression module; and
coupling the voltage transient suppression module to the inductive load module.

15) The method of claim 14 wherein:
providing the voltage transient suppression module comprises providing a snubber circuit coupled in parallel with at least part of the inductive load module, the voltage transient suppression module comprising the snubber circuit.

16) The method of claim 12 wherein:
providing the electric circuit comprises:
configuring the electric circuit to be coupled to an electric load via the inductive load module; and
configuring the electric circuit such that when the electric circuit is coupled to the electric load and the inductive load module comprises the active state, the electric circuit permits the electricity to be conducted from the electricity source to the electric load.

17) The method of claim 16 wherein:
configuring the electric circuit to be coupled to the electric load via the inductive load module comprises configuring the electric circuit to be coupled to a rechargeable energy storage system of an electric vehicle via the inductive load module, the electric vehicle comprising the rechargeable energy storage system.

18) The method of claim 11 wherein:
providing the control module comprises providing one of a computer system or an intrinsic thyristor.

19) The method of claim 11 further comprising:
providing an electric vehicle charging station, the electric vehicle charging station comprising at least one of the electric circuit or the control module.

20) A method comprising:
controlling when an inductive load module of an electric circuit receives electricity from an electricity source, the electric circuit (a) comprising the inductive load module and (b) being configured to be coupled to the electricity source, and the electricity comprising a voltage zero crossing condition and a current zero crossing condition;
wherein controlling when the inductive load module of the electric circuit receives the electricity from the electricity source comprises:
causing the inductive load module to begin receiving the electricity from the electricity source when the voltage zero crossing condition exists or begins; and
after causing the inductive load module to begin receiving the electricity from the electricity source, causing the inductive load module to stop receiving the electricity from the electricity source when the current zero crossing condition exists or begins.

21) The method of claim 20 wherein:
causing the inductive load module to begin receiving the electricity from the electricity source comprises closing at least one of a relay or a contactor, the inductive load module comprising the at least one of the relay or the contactor; and
causing the inductive load module to stop receiving the electricity from the electricity source comprises opening the at least one of the relay or the contactor.

22) The method of claim 20 further comprising:
when causing the inductive load module to stop receiving the electricity from the electricity source occurs, suppressing a voltage transient occurring at the electric circuit with a voltage transient suppression module.

23) The method of claim 20 further comprising:
after causing the inductive load module to stop receiving the electricity from the electricity source, causing the inductive load module to begin receiving the electricity from the electricity source again, wherein causing the inductive load module to begin receiving the electricity from the electricity source again occurs when the voltage zero crossing condition exists or begins again.

24) The method of claim 20 wherein:
the method is configured to be implemented as one or more computer instructions configured to be run at one or more processing module and stored at one or more memory storage modules of a computer system.

25) The method of claim 20 further comprising:
providing the electricity to an electric load via the inductive load module.

26) The method of claim 25 wherein:
providing the electricity to the electric load via the inductive load module comprises providing the electricity to a rechargeable energy storage system of an electric vehicle, the electric vehicle comprising the rechargeable energy storage system, and the electric load comprising the rechargeable energy storage system.

27) The method of claim 25 wherein:
providing the electricity to the electric load via the inductive load module occurs approximately simultaneously with causing the inductive load module to begin receiving the electricity from the electricity source.

28) The method of claim 20 wherein:
causing the inductive load module to begin receiving the electricity comprises:
receiving a start instruction indicating that the inductive load module is to receive electricity from the electricity source; and
causing the inductive load module to receive the electricity from the electricity source while or after the voltage zero crossing condition exists or begins.

29) The method of claim 20 further comprising:
after causing the inductive load module to begin receiving the electricity, causing the inductive load module to continue receiving the electricity from the electricity source until receiving a stop instruction.

30) An electric vehicle charging station comprising:
an electric circuit comprising a contactor and a voltage transient suppression module coupled in parallel with the contactor, the electric circuit being configured to be coupled to an electricity source and a rechargeable energy storage system of an electric vehicle; and
a control module configured to control when the contactor receives electricity from the electricity source, the electricity comprising an alternating current;
wherein:
when the control module permits the contactor to receive the electricity from the electricity source, the contactor is closed;
when the control module prevents the contactor from receiving the electricity from the electricity source, the contactor is open;
the electricity comprises a voltage zero crossing condition and a current zero crossing condition;
in order to control when the contactor of the electric circuit receives the electricity from the electricity source:
(a) the control module is configured to be able to cause the contactor (i) to close and (ii) to open; and
(b) the control module is further configured such that (i) when the control module causes the contactor to close, the voltage zero crossing condition exists or is beginning and (ii) when the control module causes the contactor to open, the current zero crossing condition exists or is beginning;
and
the electric circuit is configured such that when the contactor is closed and the rechargeable energy storage system is coupled to the electric circuit, the electric circuit is able to electrically charge the rechargeable energy storage system.
